(19) United States
(12) Patent Application Publication
(10) Pub. No.: US 2026/0184945 A1
(43) Pub. Date: Jul. 2, 2026

(54) ULTRAVIOLET-CURABLE RESIN COMPOSITION AND DISPLAY DEVICE

(71) Applicant: MITSUI CHEMICALS, INC., Chuo-ku, Tokyo (JP)

(72) Inventors: Kotaro TATENO, Ichihara-shi, Chiba (JP); Yusuke TOMITA, Kisarazu-shi, Chiba (JP)

(73) Assignee: MITSUI CHEMICALS, INC., Chuo-ku, Tokyo (JP)

(21) Appl. No.: 18/727,512

(22) PCT Filed: Feb. 7, 2023
(86) PCT No.: PCT/JP2023/003925

§ 371 Date: Jul. 9, 2024

(30) Foreign Application Priority Data
Feb. 8, 2022 (JP) 2022-017906

(51) Int. Cl. C09D 11/38; C08F 220/18; C08F 220/30; C09D 11/101; C09D 11/107; H10K 59/80

(52) U.S. Cl. CPC C09D 11/38; C08F 220/1806; C08F 220/302; C09D 11/101; C09D 11/107; H10K 59/873; C08F 2800/20

(57) ABSTRACT

An ultraviolet-curable resin composition containing a component which is a monofunctional aromatic (meth)acrylate having one aromatic ring and a component which is a monofunctional aromatic (meth)acrylate having two or more aromatic rings, in which a total content of the component and the component is 70 parts by mass or more with respect to 100 parts by mass of a total content of polymerizable compounds in the ultraviolet-curable resin composition.

### TECHNICAL FIELD

The present invention relates to an ultraviolet-curable resin composition and a display device.

### BACKGROUND ART

Studies have been conducted to improve characteristics of a sealing agent for a display element or the like. Hereinafter, an organic EL display device will be described as an example.

An organic EL element has been used in a display, a lighting device, or the like, because the organic EL element has a low power consumption. Since the organic EL element is easily deteriorated by moisture and oxygen in the atmosphere, it has been studied to use the organic EL element sealed with a sealing material.

Patent Document 1 (PCT Japanese Translation Patent Publication No. 2020-506251) discloses a curable ink composition containing at least one aromatic (meth)acrylate, at least one polyfunctional (meth)acrylate having a heteroaromatic group, a fused aromatic group, a heteroalkylene group, or a group including both a heteroalkylene group and an aromatic group, and a photoinitiator, in which the curable ink composition is inkjet printable, has a viscosity of 30 centipoise or less at a temperature of room temperature to 35° C., does not contain a solvent, has a refractive index of 1.55 or more, and is optically transparent in a case of being printed and cured (claim 1).

### RELATED DOCUMENT

### Patent Document

[Patent Document 1] PCT Japanese Translation Patent Publication No. 2020-506251

### SUMMARY OF THE INVENTION

### Technical Problem

In recent years, in the midst of a flat panel being a common technology, an organic EL panel held in a bent shape has been developed from the viewpoint of effective use of space and design. Furthermore, a foldable panel, a rollable panel, and a device having a high degree of freedom of movement of the device have been required.

However, on the other hand, in a case where the sealing material in such a device has a high repulsive force when bent, there is a concern that stress may be concentrated on an inorganic film or the like formed on the device due to a force trying to return to the original state, and cracks may be generated.

On the other hand, in a case where the sealing material is designed to be flexible, there is a concern that a surface hardness may be reduced and process deterioration such as surface tack and whitening may occur.

Therefore, the present invention provides a technique for obtaining a cured product having excellent flexibility and a preferred surface hardness.

### Solution to Problem

According to the present invention, an ultraviolet-curable resin composition and a display device described below are provided.

[1] An ultraviolet-curable resin composition containing:
a component (A) which is a monofunctional aromatic (meth)acrylate having one aromatic ring; and
a component (B) which is a monofunctional aromatic (meth)acrylate having two or more aromatic rings,
in which a total content of the component (A) and the component (B) is 70 parts by mass or more with respect to 100 parts by mass of a total content of polymerizable compounds in the ultraviolet-curable resin composition.

[2] The ultraviolet-curable resin composition according to [1], further containing:
a component (C) which is a tri- or higher functional (meth)acrylate.

[3] The ultraviolet-curable resin composition according to [1] or [2],
in which a viscosity measured by an E-type viscometer under conditions of 25° C. and 20 rpm is 50 mPa·s or less.

[4] The ultraviolet-curable resin composition according to any one of [1] to [3],
in which a peak value of tan δ in a viscoelasticity measurement of a cured film of the ultraviolet-curable resin composition is 1.4 or more.

[5] The ultraviolet-curable resin composition according to any one of [1] to [4],
in which a refractive index of a cured film of the ultraviolet-curable resin composition is 1.57 or more.

[6] The ultraviolet-curable resin composition according to any one of [1] to [5],
in which a glass transition temperature Tg of a cured film of the ultraviolet-curable resin composition is 60° C. or lower.

[7] The ultraviolet-curable resin composition according to any one of [1] to [6],
in which a total content of a di- or higher functional (meth)acrylate in the ultraviolet-curable resin composition is 30 parts by mass or less with respect to 100 parts by mass of the total of the polymerizable compounds.

[8] The ultraviolet-curable resin composition according to any one of [1] to [7],
in which the component (B) is a compound having a biphenyl skeleton.

[9] The ultraviolet-curable resin composition according to any one of [1] to [8],
in which the component (B) is an ether-modified aromatic (meth)acrylate.

[10] The ultraviolet-curable resin composition according to any one of [1] to [9],
in which a content of the component (C) which is the tri- or higher functional (meth)acrylate in the ultraviolet-curable resin composition is 10 parts by mass or less with respect to 100 parts by mass of the total of the polymerizable compounds.

[11] The ultraviolet-curable resin composition according to any one of [1] to [10], further containing:
a photopolymerization initiator.

[12] The ultraviolet-curable resin composition according to [11],
in which the photopolymerization initiator is diphenyl(2,4,6-trimethylbenzoyl)phosphine oxide (TPO).

[13] The ultraviolet-curable resin composition according to any one of [1] to [12],
in which the ultraviolet-curable resin composition is used for coating by an inkjet method.

[14] The ultraviolet-curable resin composition according to any one of [1] to [13],
in which the ultraviolet-curable resin composition is for a display element.

[15] The ultraviolet-curable resin composition according to [14],
in which the display element is an organic electroluminescence element.

[16] A display device including:
a substrate;
a light-emitting element disposed over the substrate; and
a resin layer covering the light-emitting element,
in which the resin layer includes a cured product of the ultraviolet-curable resin composition according to any one of [1] to [14].

[17] The display device according to [16],
in which the light-emitting element includes an organic electroluminescence element.

### Advantageous Effects of Invention

According to the present invention, it is possible to provide a technique for obtaining a cured product having excellent flexibility and a preferred surface hardness.

### BRIEF DESCRIPTION OF THE DRAWINGS

FIG. 1 is a cross-sectional view showing a configuration example of an organic EL display device according to an embodiment.

### DESCRIPTION OF EMBODIMENTS

Hereinafter, embodiments of the present invention will be described with reference to the drawings. In all the drawings, the same components are represented by common reference numerals, and the description thereof will not be repeated. In addition, in the present embodiment, for each component, one kind may be used, or two or more kinds may be used in combination. In addition, “to” representing a numerical range represents “or more” and “or less”, and includes both the upper limit value and the lower limit value.

### (Ultraviolet-Curable Resin Composition)

In the present embodiment, the ultraviolet-curable resin composition (hereinafter, also simply referred to as “resin composition” as appropriate) contains the following components (A) and (B), and a total content of the components (A) and (B) is 70 parts by mass or more with respect to 100 parts by mass of a total content of polymerizable compounds in the resin composition.
(A) A monofunctional aromatic (meth)acrylate having one aromatic ring
(B) A monofunctional aromatic (meth)acrylate having two or more aromatic rings

The present inventor has conducted studies to provide a cured product of a resin composition, having excellent flexibility and a preferred surface hardness. As a result, it has been found that a material having high bending followability can be obtained by containing the components (A) and (B) in the resin composition and controlling the total amount of the components (A) and (B). As a result, according to the present embodiment, it is possible to obtain an excellent balance between flexibility and surface hardness of the cured product of the resin composition.

In addition, according to the present embodiment, it is also possible to obtain a cured product having, for example, excellent flexibility and an excellent effect of suppressing process deterioration.

Hereinafter, the configuration of the resin composition will be described in more detail. First, constituent components of the resin composition will be described with specific examples.

### (Polymerizable Compound)

The resin composition according to the present embodiment contains a polymerizable compound, and the polymerizable compound includes the following components (A) and (B). The polymerizable compound is specifically a compound having a radical polymerizable functional group such as a (meth)acryloyl group.

Here, in the present specification, the (meth)acryloyl group means at least one of an acryloyl group or a methacryloyl group. In addition, the (meth)acrylic means at least one of acrylic or methacrylic. In addition, the (meth)acrylate means at least one of acrylate or methacrylate. In addition, EO is ethylene oxide.

### (Component (A))

The component (A) is a monofunctional aromatic (meth)acrylate having one aromatic ring.

Specific examples of the component (A) include benzyl acrylate (for example, Viscoat #160, manufactured by OSAKA ORGANIC CHEMICAL INDUSTRY LTD.); phenoxy group-containing (meth)acrylates such as phenoxyethyl (meth)acrylate (for example, Viscoat #192); phenol EO-modified (meth)acrylate (for example, ARONIX (registered trademark) M-101A (EO-added molar number≈2) and M-102 (EO-added molar number≈4), both manufactured by TOAGOSEI CO., LTD.); and alkylphenol-EO-modified (meth)acrylates such as nonylphenol EO-modified acrylate (for example, ARONIX (registered trademark) M-111 (EO-added molar number≈1) and M-113 (EO-added molar number≈4), both manufactured by TOAGOSEI CO., LTD.).

From the viewpoint of adjusting the viscosity to improve coating properties and maintaining the surface hardness, a content of the component (A) in the resin composition is more than 0 parts by mass, preferably 5 parts by mass or more, more preferably 10 parts by mass or more, still more preferably 15 parts by mass or more, and even more preferably 20 parts by mass or more, with respect to 100 parts by mass of the total content of the polymerizable compounds in the resin composition.

In addition, from the viewpoint of enhancing the flexibility, the content of the component (A) in the resin composition is less than 100 parts by mass, preferably 80 parts by mass or less, more preferably 60 parts by mass or less, still more preferably 50 parts by mass or less, and even more preferably 40 parts by mass or less, with respect to 100 parts by mass of the total content of the polymerizable compounds in the resin composition.

### (Component (B))

The component (B) is a monofunctional aromatic (meth)acrylate having two or more aromatic rings.

Specific examples of the component (B) include a biphenyl skeleton-containing (meth)acrylate such as an ethoxylated o-phenylphenol acrylate (for example, A-LEN-10, manufactured by SHIN-NAKAMURA CHEMICAL CO, LTD.), and a phenoxyphenyl skeleton-containing (meth)acrylate (for example, POB-A, manufactured by Kyoeisha Chemical Co., Ltd.).

From the viewpoint of high flexibility and ability to maintain the surface hardness, the component (B) is preferably a compound having a biphenyl skeleton.

In addition, the component (B) may be, for example, an ether-modified aromatic (meth)acrylate such as ethoxylated o-phenylphenol acrylate (for example, A-LEN-10, manufactured by SHIN-NAKAMURA CHEMICAL CO, LTD.).

From the viewpoint of improving flexibility and improving refractive index, a content of the component (B) in the resin composition is more than 0 parts by mass, preferably 20 parts by mass or more, more preferably 40 parts by mass or more, still more preferably 50 parts by mass or more, and even more preferably 55 parts by mass or more, with respect to 100 parts by mass of the total content of the polymerizable compounds in the resin composition.

In addition, from the viewpoint of improving inkjet jettability, the content of the component (B) in the resin composition is less than 100 parts by mass, preferably 90 parts by mass or less, more preferably 80 parts by mass or less, and still more preferably 70 parts by mass or less, with respect to 100 parts by mass of the total content of the polymerizable compounds in the resin composition.

From the viewpoint of achieving both flexibility and surface hardness, the total content of the components (A) and (B) in the resin composition is 70 parts by mass or more, preferably 75 parts by mass or more, more preferably 80 parts by mass or more, and still more preferably 90 parts by mass or more, with respect to 100 parts by mass of the total content of the polymerizable compounds in the resin composition.

In addition, from the viewpoint of adjusting the viscosity for inkjet jettability, the total content of the components (A) and (B) in the resin composition is 100 parts by mass or less, and may be, for example, 98 parts by mass or less, with respect to 100 parts by mass of the total content of the polymerizable compounds in the resin composition.

The resin composition may contain a polymerizable compound other than the components (A) and (B).

Examples of the polymerizable compound other than the components (A) and (B) include the following component (C).

### (Component (C))

The component (C) is a tri- or higher functional (meth)acrylate.

Specific examples of the component (C) include trifunctional (meth)acrylic compounds such as trimethylolpropane triacrylate (for example, A-TMPT, manufactured by SHIN-NAKAMURA CHEMICAL CO, LTD., and Light acrylate TMP-A, manufactured by Kyoeisha Chemical Co., Ltd.), ethoxylated trimethylolpropane triacrylate (for example, A-TMPT-EO, manufactured by SHIN-NAKAMURA CHEMICAL CO, LTD.), ethoxylated glycerin triacrylate (for example, A-GLY-6E, manufactured by SHIN-NAKAMURA CHEMICAL CO, LTD.), propoxylated glycerin triacrylate (for example, A-GLY-3P, manufactured by SHIN-NAKAMURA CHEMICAL CO, LTD.), trimethylolpropane trimethacrylate (for example, TMPT, manufactured by SHIN-NAKAMURA CHEMICAL CO, LTD.), and tris-(2-acryloxyethyl) isocyanurate (for example, A-9300, manufactured by SHIN-NAKAMURA CHEMICAL CO, LTD.);
tetrafunctional (meth)acrylic compounds such as pentaerythritol tetraacrylate (for example, A-TMMT, manufactured by SHIN-NAKAMURA CHEMICAL CO, LTD.), ethoxylated pentaerythritol tetraacrylate (for example, ATM-4E, manufactured by SHIN-NAKAMURA CHEMICAL CO, LTD.), and ditrimethylolpropane tetraacrylate (for example, AD-TMP-L, manufactured by SHIN-NAKAMURA CHEMICAL CO, LTD.);
a pentafunctional (meth)acrylate compound such as dipentaerythritol pentaacrylate; and
a hexafunctional (meth)acrylic compound such as dipentaerythritol hexaacrylate (for example, GM66G0H, manufactured by Qualipoly Chemical Corp.).

In addition, examples of a mixture of dipentaerythritol pentaacrylate and dipentaerythritol hexaacrylate include M-402 (manufactured by TOAGOSEI CO., LTD.).

From the viewpoint of reducing plasticity and reducing damage to the organic EL element in a plasma treatment process, a content of the component (C) in the resin composition is, for example, 0 parts by mass or more, preferably 1 part by mass or more, more preferably 2 parts by mass or more, still more preferably 3 parts by mass or more, even more preferably 4 parts by mass or more, and even still more preferably 4.8 parts by mass or more, with respect to 100 parts by mass of the total content of the polymerizable compounds in the resin composition.

In addition, from the viewpoint of maintaining the flexibility, the content of the component (C) in the resin composition is 30 parts by mass or less, preferably 10 parts by mass or less, more preferably 8 parts by mass or less, and still more preferably 5 parts by mass or less, with respect to 100 parts by mass of the total content of the polymerizable compounds in the resin composition.

In addition, from the viewpoint of maintaining the flexibility, the total content of the di- or higher functional (meth)acrylate in the resin composition is 30 parts by mass or less, preferably 20 parts by mass or less, more preferably 10 parts by mass or less, and still more preferably 5 parts by mass or less, with respect to 100 parts by mass of the total content of the polymerizable compounds in the resin composition.

In addition, from the viewpoint of reducing plasticity, the total content of the di- or higher functional (meth)acrylate in the resin composition is, for example, 0 parts by mass or more, preferably 1 part by mass or more, more preferably 2 parts by mass or more, and still more preferably 3 parts by mass or more, with respect to 100 parts by mass of the total content of the polymerizable compounds in the resin composition.

Here, among the di- or higher functional (meth)acrylates, specific examples of the tri- or higher functional (meth)acrylates include the above-described compounds.

In addition, specific examples of the difunctional (meth)acrylate include di(meth)acrylate of a diol and di(meth)acrylate of a (poly)alkylene glycol, and more specific examples thereof include 1,6-hexanediol diacrylate (for example, A-HD-N, manufactured by SHIN-NAKAMURA CHEMICAL CO, LTD.), 1,9-nonanediol diacrylate (for example, A-NOD-N, manufactured by SHIN-NAKAMURA CHEMICAL CO, LTD., Light acrylate 1,9ND-A, manufactured by Kyoeisha Chemical Co., Ltd. and Viscoat 260, manufactured by OSAKA ORGANIC CHEMICAL INDUSTRY LTD.), 1,10-decanediol diacrylate (for example, A-DOD-N, manufactured by SHIN-NAKAMURA CHEMICAL CO, LTD.), neopentyl glycol diacrylate (for example, A-NPG, manufactured by SHIN-NAKAMURA CHEMICAL CO, LTD., and Light acrylate NP-A, manufactured by Kyoeisha Chemical Co., Ltd.), ethylene glycol diacrylate (for example, SR206NS, manufactured by Arkema), polyethylene glycol diacrylate (for example, A-400, manufactured by SHIN-NAKAMURA CHEMICAL CO, LTD.), polypropylene glycol diacrylate (for example, APG-400, manufactured by SHIN-NAKAMURA CHEMICAL CO, LTD.), tricyclodecanedimethanol diacrylate (dimethylol-tricyclodecane diacrylate) (for example, A-DCP, manufactured by SHIN-NAKAMURA CHEMICAL CO, LTD., and Light acrylate DCP-A, manufactured by Kyoeisha Chemical Co., Ltd.), 1,3-butanediol dimethacrylate (for example, BG, manufactured by SHIN-NAKAMURA CHEMICAL CO, LTD.), 1,4-butanediol dimethacrylate (for example, BD, manufactured by SHIN-NAKAMURA CHEMICAL CO, LTD.), 1,6-hexanediol dimethacrylate (for example, HD-N, manufactured by SHIN-NAKAMURA CHEMICAL CO, LTD.), 1,9-nonanediol dimethacrylate (for example, NOD-N, manufactured by SHIN-NAKAMURA CHEMICAL CO, LTD.), 1,10-decanediol dimethacrylate (for example, DOD-N, manufactured by SHIN-NAKAMURA CHEMICAL CO, LTD.), 1,12-dodecanediol dimethacrylate (for example, SR-262, manufactured by Sartomer), neopentyl glycol dimethacrylate (for example, NPG, manufactured by SHIN-NAKAMURA CHEMICAL CO, LTD.), and tricyclodecanedimethanol dimethacrylate (for example, DCP, manufactured by SHIN-NAKAMURA CHEMICAL CO, LTD.).

From the viewpoint of making the cured product more preferable in terms of flexibility and surface hardness, a content of the difunctional (meth)acrylate is preferably 10% by mass or less, more preferably 7% by mass or less, still more preferably less than 5% by mass, even more preferably less than 2% by mass, and even still more preferably 1% by mass or less, with respect to the total formulation of the resin composition.

In addition, from the viewpoint of making the cured product more preferable in terms of flexibility and surface hardness, the content of the difunctional (meth)acrylate is preferably 35 parts by mass or less, more preferably 25 parts by mass or less, still more preferably 15 parts by mass or less, even more preferably 5 parts by mass or less, even still more preferably 3 parts by mass or less, and further more preferably 1 part by mass or less, with respect to 100 parts by mass of the total content of the polymerizable compounds in the resin composition.

From the viewpoint of improving strength of the cured product, the total content of the polymerizable compounds in the resin composition is preferably 70% by mass or more, more preferably 80% by mass or more, still more preferably 85% by mass or more, and even more preferably 90% by mass or more, with respect to the total formulation of the resin composition.

In addition, the total content of the polymerizable compounds in the resin composition is, for example, 99.9% by mass or less, preferably 99.5% by mass or less and more preferably 99% by mass or less, with respect to the total formulation of the resin composition.

In the present embodiment, the resin composition may contain a component other than the polymerizable compounds.

Examples of other components include a polymerization initiator, a pressure-sensitive adhesive imparting agent (tackifier), a photosensitizer, a leveling agent, and a coupling agent such as a silane coupling agent.

### (Polymerization Initiator)

In the present embodiment, the resin composition specifically further contains a polymerization initiator, and preferably further contains a photopolymerization initiator.

The photopolymerization initiator is specifically a photoradical generator.

Specific examples of the photoradical generator include one or two or more selected from the group consisting of an acyloxy phosphide compound, an oxime ester compound, an alkylphenone compound, and a benzophenone derivative.

Specific examples of the acyloxy phosphide compound include 2,4,6-trimethylbenzoyldiphenylphosphine oxide (TPO; for example, Omnirad TPO, manufactured by IGM Resins R.V.), and bis(2,4,6-trimethylbenzoyl)phenylphosphine oxide (for example, Omnirad 819, manufactured by IGM Resins R.V.).

In addition, specific examples of the oxime ester compound include Irgacure OXE01, Irgacure OXE02, Irgacure OXE03, and Irgacure OXE04.

From the viewpoint of improving curability, the photopolymerization initiator is preferably TPO.

From the viewpoint of improving the curability, a content of the polymerization initiator in the resin composition is preferably 0.1 parts by mass or more, more preferably 1 part by mass or more, and still more preferably 2 parts by mass or more, with respect to 100 parts by mass of the total of the resin composition.

In addition, from the viewpoint of suppressing coloring of the resin composition, the content of the polymerization initiator in the resin composition is preferably 10 parts by mass or less, more preferably 8 parts by mass or less, still more preferably 6 parts by mass or less, and even more preferably 4 parts by mass or less, with respect to 100 parts by mass of the total of the resin composition.

### (Pressure-Sensitive Adhesive Imparting Agent)

In a case where the resin composition contains a pressure-sensitive adhesive imparting agent, an internal stress of the resin composition can be relaxed without significantly changing the refractive index of the cured product of the resin composition, and more specifically, an internal stress of the resin composition during curing can be reduced.

Specific examples of the pressure-sensitive adhesive imparting agent include at least one resin selected from the group consisting of a petroleum resin such as an aliphatic hydrocarbon resin, an alicyclic hydrocarbon resin, and an aromatic hydrocarbon resin; a terpene resin; a phenol resin; a terpene phenol resin; and a rosin resin.

Specific examples of the petroleum resin include a C5 monomer obtained from pentene, pentadiene, isoprene, or the like, or an oligomer thereof; a C9 monomer obtained from indene, methylindene, vinyltoluene, styrene, α-methylstyrene, β-methylstyrene, or the like, or an oligomer thereof; a copolymer of the C5 monomer and the C9 monomer (C5-C9 copolymer resin); an alicyclic monomer obtained from cyclopentadiene, dicyclopentadiene, or the like, or a polymer thereof; an aromatic monomer obtained from isopropenyltoluene, or a polymer thereof; a hydride of the above-mentioned various monomers or polymers thereof; and a modified petroleum resin obtained by modifying the above-mentioned various monomers or polymers thereof with maleic anhydride, maleic acid, fumaric acid, (meth)acrylic acid, phenol, or the like.

From the viewpoint of excellent compatibility with the polymerizable compounds, the petroleum resin is preferably a styrene oligomer.

Specific examples of the terpene resin include an α-pinene resin, a β-pinene resin, and an aromatic-modified terpene-based resin obtained by copolymerizing terpenes such as an α-pinene monomer and a β-pinene monomer with an aromatic monomer such as styrene.

Specific examples of the phenol resin include a condensate of phenols and formaldehyde. Examples of the phenols include phenol, m-cresol, 3,5-xylenol, p-alkylphenol, and resorcinol. Examples of the phenol resin include resol obtained by subjecting these phenols and formaldehyde to an addition reaction with an alkali catalyst; and novolac obtained by subjecting these phenols and formaldehyde to a condensation reaction with an acid catalyst. In addition, the phenol resin also includes a rosin-phenol resin obtained by adding phenol to rosin in the presence of an acid catalyst and thermally polymerizing the mixture.

In addition, examples of the terpene phenol resin include a copolymer of terpenes and phenols.

Specific examples of the rosin resin include gum rosin, wood rosin, or tall oil rosin; stabilized rosin or polymerized rosin obtained by disproportionation or hydrogenation treatment using these rosins; modified rosin obtained by modifying these rosins with maleic anhydride, maleic acid, fumaric acid, (meth)acrylic acid, phenol, or the like; and esterification products thereof. The alcohol used to obtain the esterification product is preferably a polyhydric alcohol. Examples of the polyhydric alcohol include one or two or more selected from the group consisting of dihydric alcohols such as ethylene glycol, diethylene glycol, propylene glycol, and neopentyl glycol; trihydric alcohols such as glycerin, trimethylolethane, and trimethylolpropane; tetrahydric alcohols such as pentaerythritol and diglycerin; and hexahydric alcohols such as dipentaerythritol.

From the viewpoint of making the resin composition more preferable in terms of viscosity and inkjet applicability, a content of the pressure-sensitive adhesive imparting agent in the resin composition is preferably 0.5% by mass or more, more preferably 1% by mass or more, and still more preferably 1.5% by mass or more, and is preferably 10% by mass or less, more preferably 8% by mass or less, and still more preferably 5% by mass or less, with respect to the total formulation of the resin composition.

### (Leveling Agent)

In a case where the resin composition further contains a leveling agent, flatness of a film formed of the resin composition can be improved.

Specific examples of the leveling agent include silicone-based leveling agents such as polyester-modified polydimethylsiloxane (for example, BYK-310, manufactured by BYK Japan K. K.) and polyether-modified siloxane (for example, BYK-345, manufactured by BYK Japan K. K.);
acrylic leveling agents such as an acrylic copolymer (for example, BYK-350, manufactured by BYK Japan K. K., KL700, manufactured by Kyoeisha Chemical Co., Ltd., and POLYFLOW No. 90, manufactured by Kyoeisha Chemical Co., Ltd.); and
fluorine-based leveling agents such as a fluorine-modified polymer (for example, BYK-340, manufactured by BYK Japan K. K.) and a perfluoroalkyl-containing oligomer (for example, Surflon S-611 (manufactured by AGC SEIMI CHEMICAL CO., LTD.).

From the viewpoint of improving the flatness in a case where the resin composition is applied to inkjet printing, the leveling agent is preferably one or two or more selected from the group consisting of an acrylic copolymer, a polyester-modified polydimethylsiloxane, and a fluorine-modified polymer.

From the same viewpoint, it is also preferable that the leveling agent is an acrylic leveling agent.

From the viewpoint of improving the flatness of the film formed of the resin composition, a content of the leveling agent in the resin composition is preferably 0.01% by mass or more, more preferably 0.05% by mass or more, still more preferably 0.1% by mass or more, and even still more preferably 0.5% by mass or more, with respect to the total formulation of the resin composition.

In addition, from the viewpoint of stabilizing the surface hardness of the cured product, the content of the leveling agent in the resin composition is preferably 5% by mass or less, more preferably 3% by mass or less, and still more preferably 2% by mass or less, with respect to the total formulation of the resin composition.

### (Solvent)

In the present embodiment, the resin composition is preferably a resin composition which does not contain a solvent, or in a case where the resin composition contains a solvent, a content of the solvent is more than 0% by mass and 0.05% by mass or less, more preferably 0.03% by mass or less. Specific examples of the aspect in which the resin composition does not contain a solvent include a resin composition in which the solvent is not intentionally blended at the time of preparing the resin composition.

From the viewpoint of being suitable for jetting from an inkjet nozzle, in the present embodiment, the resin composition is preferably liquid.

From the viewpoint of improving an effect of preventing liquid dripping at the time of inkjet jetting, a viscosity of the resin composition, measured using an E-type viscometer at 25° C. and 20 rpm, is preferably 1 mPa·s or more, more preferably 4 mPa·s or more, still more preferably 7 mPa·s or more, even more preferably 10 mPa·s or more, even still more preferably 13 mPa·s or more, and further more preferably 16 mPa·s or more.

In addition, from the viewpoint of enabling more stable inkjet jetting, the above-described viscosity of the resin composition is preferably 50 mPa·s or less, more preferably 35 mPa·s or less, and still more preferably 30 mPa·s or less.

From the viewpoint of improving the flexibility while maintaining the hardness, a peak value of tan δ in a viscoelasticity measurement of the cured film of the resin composition is preferably 1.40 or more, more preferably 1.60 or more, still more preferably 1.75 or more, even more preferably 1.80 or more, and even still more preferably 1.9 or more.

In addition, the above-described peak value of tan & may be, for example, 10.0 or less.

From the viewpoint of improving the flexibility, a glass transition temperature Tg of the cured film of the resin composition is preferably 60° C. or lower, more preferably 55° C. or lower, still more preferably 50° C. or lower, even more preferably 45° C. or lower, and even still more preferably 40° C. or lower.

In addition, from the viewpoint of suppressing surface tackiness, the Tg is preferably −10° C. or higher, more preferably 0° C. or higher, still more preferably 10° C. or higher, and even more preferably 20° C. or higher.

Here, the peak value of tan δ and Tg in the viscoelasticity measurement of the cured film of the resin composition are measured by the following method.

### (Method for Producing Cured Film)

The resin composition is enclosed in two glass plates with a Teflon (registered trademark) sheet having a thickness of 100 μm interposed therebetween, and cured with a UV-LED having a wavelength of 395 nm at an illuminance of 1,000 mW/cm² and an integrated light amount of 4,000 mJ/cm² to obtain a cured product having a thickness of 100 μm. Thereafter, the cured product is cut to a size of 5 mm in width and 45 mm in length, and a cured product having a thickness of 90 to 110 μm at a total of 4 points every 10 mm in a length direction is used as a sample.

### (Measurement Method of Tan δ and Tg)

The measurement is performed in accordance with JIS K 7244-4:1999. Specifically, using a dynamic viscoelasticity measuring device “DMS6100” (manufactured by Seiko Instruments Inc.), a dynamic viscoelasticity of the obtained cured film is measured at a frequency of 1 Hz, a temperature range of 25° C. to 150° C., and a temperature rising rate of 5° C./min; a storage elastic modulus E′ and a loss elastic modulus E″ thereof are measured; a loss tangent, that is, tan δ=loss elastic modulus E″/storage elastic modulus E′ is obtained; and the maximum value thereof is defined as the peak value of tan δ. In addition, the temperature at which the tan δ is maximum is defined as the glass transition temperature Tg.

From the viewpoint of imparting excellent flexibility by intermolecular interaction, a refractive index of the cured film of the resin composition is preferably 1.57 or more, more preferably 1.575 or more, still more preferably 1.58 or more, and even more preferably 1.59 or more.

In addition, the above-described refractive index may be, for example, 1.70 or less.

Here, the cured film of the resin composition, which is a sample for measuring the refractive index, is produced in the same manner as the sample for measuring tan δ.

In addition, the refractive index of the cured film is specifically a refractive index (nd) of the cured product at room temperature (25° C.) in a d-line (wavelength: 587.6 nm), and the refractive index of the cured film can be measured by an Abbe refractometer based on JIS standard K0062-1992.

Next, a method for producing the resin composition will be described.

The method for producing the resin composition is not limited, and includes, for example, mixing the components (A) and (B), and other components as appropriate. Examples of the method of mixing the respective components include a method of uniformly kneading the respective components under conditions of room temperature, heating, normal pressure, reduced pressure, pressurization, or an inert gas stream using, for example, various known kneaders such as a planetary stirring device, a homodisper, a universal mixer, a Banbury mixer, a kneader, two-roll, three-roll, and an extruder alone or in combination.

In the present embodiment, a sealing material can also be formed of the obtained resin composition. For example, the resin composition may be applied onto a base material and dried. As the coating, a known method such as an inkjet method, screen printing, and dispenser coating can be used. In addition, the drying can be performed by heating the resin composition to a temperature at which the polymerizable compounds are not polymerized. A shape of the obtained sealing material is not limited, and for example, the sealing material can be in a form of a film.

In addition, the resin composition according to the present embodiment is suitably used for coating by an inkjet method.

The resin composition according to the present embodiment is preferably for a display element, and more preferably for an organic electroluminescence (EL) element.

In addition, the resin composition according to the present embodiment is preferably suitably used as a sealing material for a display element such as an organic EL element.

In addition, by using the cured product of the resin composition obtained in the present embodiment as the sealing material for a display element such as an organic EL display element, it is possible to obtain a display device having excellent production stability and design flexibility.

Hereinafter, a configuration example of the organic EL display device will be described.

### (Organic EL Display Device)

In the present embodiment, the organic EL display device has a layer formed of the cured product of the resin composition.

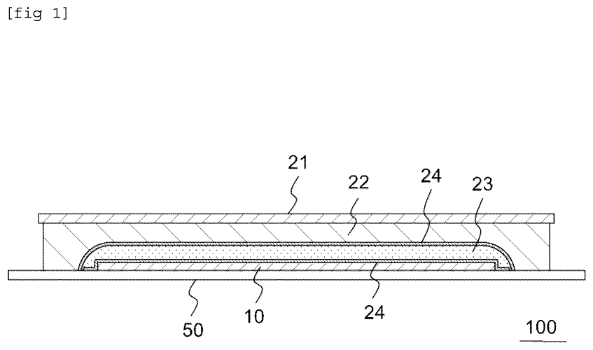

FIG. 1 is a cross-sectional view showing a configuration example of the organic EL display device according to the present embodiment. A display device 100 shown in FIG. 1 is an organic EL display device, and includes a substrate (base material layer 50), an organic EL element (light-emitting element 10) disposed over the base material layer 50, and a sealing layer 22 (which may be an overcoat layer 22 or a barrier layer 22) covering the light-emitting element 10. For example, the sealing layer 22 is formed of the cured product of the resin composition according to the present embodiment.

In addition, in FIG. 1, the display device 100 has a barrier layer 21 (which may be a touch panel layer 21 or a surface protective layer 21), a sealing layer 22 (which may be an overcoat layer 22 or a barrier layer 22), a flattening layer 23 (which may be a sealing layer 23), and a barrier layer 24, as layers which are positioned on an observation side with respect to the light-emitting element 10. The flattening layer 23 is provided on the base material layer 50 to cover the light-emitting element 10, and the barrier layer 24 is provided on a surface of the flattening layer 23. The sealing layer 22 is provided on the base material layer 50 to cover the flattening layer 23 and the barrier layer 24. In addition, the barrier layer 21 is provided on the sealing layer 22.

The specific configuration of each layer is not limited, and an appropriate configuration can be adopted based on generally known information. In addition, such a display device 100 can be manufactured based on generally known information.

### EXAMPLES

Hereinafter, the present invention will be described with reference to Examples, Comparative Examples, and Reference Example, but the present invention is not limited thereto.

First, materials used in the following examples are shown.

### (Polymerizable Compound)

(A) Polymerizable compound 1 (monofunctional aromatic acrylate): benzyl acrylate (CAS No. 2495-35-4), Viscoat #160, manufactured by OSAKA ORGANIC CHEMICAL INDUSTRY LTD.

(B) Polymerizable compound 2 (monofunctional aromatic acrylate): ethoxylated o-phenylphenol acrylate (CAS No. 72009-86-0), A-LEN-10, manufactured by SHIN-NAKAMURA CHEMICAL CO, LTD.

(A) Polymerizable compound 3 (monofunctional aromatic acrylate): nonylphenol EO-modified acrylate (EO-added molar number≈1), ARONIX (registered trademark) M-111, manufactured by TOAGOSEI CO., LTD.

Polymerizable compound 4 (difunctional methacrylate): 1,12-dodecanediol dimethacrylate (CAS No. 72829-09-5), SR-262, manufactured by Sartomer

Polymerizable compound 5 (difunctional methacrylate): 1,9-nonanediol dimethacrylate (CAS No. 65833-30-9), NOD-N, manufactured by SHIN-NAKAMURA CHEMICAL CO, LTD.

Polymerizable compound 6 (monofunctional acrylate): Isostearyl acrylate (CAS No. 93841-48-6), S1800A, manufactured by SHIN-NAKAMURA CHEMICAL CO, LTD.

(C) Polymerizable compound 7 (penta- and hexa-functional acrylate): mixed product of dipentaerythritol pentaacrylate and dipentaerythritol hexaacrylate (mixed product of CAS No. 60506-81-2 and 29570-58-9), M-402, manufactured by TOAGOSEI CO., LTD.

(C) Polymerizable compound 8 (trifunctional acrylate): tris-(2-acryloxyethyl) isocyanurate (CAS No. 40220-08-4), A-9300, manufactured by SHIN-NAKAMURA CHEMICAL CO, LTD.

(C) Polymerizable compound 9 (trifunctional acrylate): trimethylolpropane triacrylate (CAS No. 15625-89-5), A-TMPT, manufactured by SHIN-NAKAMURA CHEMICAL CO, LTD.

### (Tackifier)

Tackifier 1: aromatic hydrocarbon resin 1; styrene oligomer A, homopolymer of isopropenyl toluene (IPT) (weight-average molecular weight: 1,200, number-average molecular weight: 800)

### (Leveling Agent)

Leveling agent 1: acrylic copolymer, POLYFLOW No. 90, manufactured by Kyoeisha Chemical Co., Ltd.

### (Polymerization Initiator)

Photopolymerization initiator 1: 2,4,6-trimethylbenzoyl-diphenylphosphine oxide, TPO, manufactured by IGM Resins R. V.

### Examples 1 to 12, Comparative Examples 1 and 2, and Reference Example 1

The respective components were blended to have the blending formulation shown in Table 1 to obtain a resin composition that was a curable composition which was liquid and contained no solvent.

Physical properties of the resin composition or the cured product thereof, obtained in each of Examples, were measured by the following methods. The measurement results are shown in Table 1.

### (Viscosity)

The viscosity of the resin composition obtained in each of Examples was measured using an E-type viscometer (LV DV-II+ Pro, manufactured by Brookfield) at 25° C. and 20 rpm.

### (tan δ and Tg)

The peak value of tan δ and Tg of the cured film of the resin composition, obtained in each of Examples, were measured by the following method.

The resin composition was enclosed in two glass plates with a Teflon (registered trademark) sheet having a thickness of 100 μm interposed therebetween, and cured with a UV-LED having a wavelength of 395 nm at an illuminance of 1,000 mW/cm² and an integrated light amount of 4,000 mJ/cm² to obtain a cured product. Thereafter, the cured product was cut to a size of 5 mm in width and 45 mm in length, and a cured product (self-supporting film) having a thickness of 90 to 110 μm at a total of 4 points every 10 mm in a length direction was used as a sample.

For the obtained cured film, a dynamic viscoelasticity was measured by a tensile test of dynamic mechanical analysis (DMS; DMS6100, manufactured by Seiko Instruments Inc.) in accordance with JIS K7244-4:1999 under conditions of a frequency of 1 Hz, a temperature rising rate of 5° C./min, a temperature range of 23° C. to 150° C., a strain amplitude of 5 μm, a minimum tension/compression force of 50 mN, a tension/compression force gain of 1.2, an initial force amplitude of 50 mN, a sampling of 3 s, a chuck distance of 20 mm, and a rate of 98.0665 mN/min in SS control mode; a storage elastic modulus E′ and a loss elastic modulus E″ thereof were measured; a loss tangent, that is, tan δ=loss elastic modulus E″/storage elastic modulus E′ was obtained; and the maximum value thereof was defined as the peak value of tan δ.

In addition, the temperature at which the tan δ was maximum was defined as the glass transition temperature Tg (° C.).

### (Refractive Index)

The refractive index of the cured film of the resin composition, obtained in each of Examples, was measured by the following method.

The refractive index (nd) of the cured film at a d-line (wavelength: 587.6 nm) at room temperature (25° C.) was obtained by measuring the refractive index of the cured film with an Abbe refractometer based on JIS standard: K0062-1992.

### (CVD)

As an index of damage to the organic EL element in a plasma treatment process, CVD evaluation was performed by the following method.

A coating film for obtaining a cured product for CVD evaluation was produced by the following method. That is, the resin composition obtained in each of Examples was introduced into an inkjet cartridge DMC-11610 (manufactured by FUJIFILM Dimatix, Inc.). The inkjet cartridge was set in an inkjet device DMP-2831 (manufactured by FUJIFILM Dimatix, Inc.), the jetting state was adjusted, and then the coating was performed on the alkali-free glass in a size of 5 cm×5 cm so that a thickness after curing was 10 μm.

The obtained coating film was cured with a UV-LED having a wavelength of 395 nm at an illuminance of 1,000 mW/cm², an integrated light amount of 4,000 mJ/cm², and an oxygen concentration of 1,000 ppm or less.

Thereafter, aluminum was deposited on the inkjet coating surface with a thickness of 100 nm, and a dielectric constant was measured at a condition of 100 kHz by an automatic balance bridge method using an LCR meter HP4284A (manufactured by Agilent Technologies, Inc.).

A film of SiN, having a refractive index of 1.7 and a thickness of 1 μm, was formed on the obtained sample by a parallel flat plate method at 110° C. A state after the film formation was evaluated according to the following standard, and those of A and B were regarded as acceptable.
C: peeling was observed.
B: partial peeling was observed.
A: no peeling was observed.

### (Inkjet Jetting Stability)

The resin composition obtained in each of Examples was put into an inkjet cartridge DMC-11610 (manufactured by FUJIFILM Dimatix, Inc.; number of nozzles: 16), a jetting state was adjusted, and then the inkjet cartridge was stored at 25° C. and 50% RH for 90 days and jetted. A case where the number of non-jetting nozzles at this time was less than 30% was evaluated as A, and a case where the number of non-jetting nozzles was 30% or more was evaluated as B.

### (Film Bending Following Test)

As an index of the surface hardness and the flexibility of the cured film, a self-supporting film of the resin composition, obtained in each of Examples, was produced by the following method, and a film bending following test was performed.

The cured film (self-supporting film) was produced according to the above-described method in the method for measuring the tan δ and Tg, except that the width of the cured product was set to 30 mm.

The obtained self-supporting film was wound around a smooth rod (made of stainless steel) having a diameter of 1 cm at 25° C.; and when the self-supporting film was returned, a case where the self-supporting film was broken was evaluated as D, a case where the self-supporting film was partially broken was evaluated as C, a case where the self-supporting film was firmly adhered by tacking was evaluated as B, and a case where the self-supporting film was neither broken nor firmly adhered was evaluated as A. Those of A to C were regarded as acceptable.

TABLE 1

| | | Exam- | Exam- | Exam- | Exam- | Exam- | Exam- | Exam- | Exam- |
|---|---|---|---|---|---|---|---|---|---|
| | | ple 1 | ple 2 | ple 3 | ple 4 | ple 5 | ple 6 | ple 7 | ple 8 |
| (A) Polymerizable | Monofunctional | 35 | 35 | 35 | 33.3 | 26.5 | 35 | 24.5 | 36.9 |
| compound 1 | acrylate | | | | | | | | |
| | (aromatic) | | | | | | | | |
| (B) Polymerizable | Monofunctional | 60 | 60 | 60 | 57.2 | 68.6 | 60 | 70.6 | 63.1 |
| compound 2 | acrylate | | | | | | | | |
| | (aromatic) | | | | | | | | |
| (A) Polymerizable | Monofunctional | | | | | | | | |
| compound 3 | acrylate | | | | | | | | |
| | (aromatic) | | | | | | | | |
| Polymerizable | Difunctional | | | | | | | | |
| compound 4 | methacrylate | | | | | | | | |
| Polymerizable | Difunctional | | | | | | | | |
| compound 5 | methacrylate | | | | | | | | |
| Polymerizable | Monofunctional | | | | | | | | |
| compound 6 | acrylate | | | | | | | | |
| (C) Polymerizable | Penta- and hexa- | 5 | | | | 4.9 | | 4.9 | |
| compound 7 | functional | | | | | | | | |
| | acrylate | | | | | | | | |
| (C) Polymerizable | Trifunctional | | | | | | 5 | | |
| compound 8 | acrylate | | | | | | | | |
| (C) Polymerizable | Trifunctional | | 5 | 5 | 9.5 | | | | |
| compound 9 | acrylate | | | | | | | | |
| Tackifier 1 | Tackifier | | 2 | | | | | | |
| Leveling | Leveling | 1 | 1 | 1 | 1 | 1 | 1 | 1 | 1 |
| agent 1 | agent | | | | | | | | |
| Photopolymerization | Curing | 3 | 3 | 3 | 3 | 3 | 3 | 3 | 3 |
| initiator 1 | agent | | | | | | | | |
| Physical | tan δ | 2.5 | 2.5 | 2.9 | 1.9 | 2.4 | 3 | 2.5 | 3.5 |
| properties | Tg (° C.) | 29 | 33 | 31 | 33 | 31 | 30 | 32 | 27 |
| | Refractive | 1.59 | 1.59 | 1.59 | 1.59 | 1.6 | 1.59 | 1.6 | 1.59 |
| | index | | | | | | | | |
| | Viscosity @25° C. | 19 | 22 | 19 | 27 | 25 | 21 | 29 | 16 |
| Evaluation | CVD | A | A | A | A | A | A | A | B |
| | Inkjet | A | A | A | A | A | A | A | A |
| | jetting | | | | | | | | |
| | stability | | | | | | | | |
| | Film | A | A | A | A | A | A | A | B |
| | bending | | | | | | | | |
| | following | | | | | | | | |
| | test | | | | | | | | |

| | | | | | | Compar- | Compar- | Refer- |
|---|---|---|---|---|---|---|---|---|
| | | | | | | ative | ative | ence |
| | | Exam- | Exam- | Exam- | Exam- | Exam- | Exam- | Exam- |
| | | ple 9 | ple 10 | ple 11 | ple 12 | ple 1 | ple 2 | ple 1 |
| (A) Polymerizable | Monofunctional | 21 | 28.6 | 70.8 | 29.5 | 22.1 | 11.1 | |
| compound 1 | acrylate | | | | | | | |
| | (aromatic) | | | | | | | |
| (B) Polymerizable | Monofunctional | 69 | 61.9 | 23.1 | 50.5 | 37.9 | 18.9 | 20 |
| compound 2 | acrylate | | | | | | | |
| | (aromatic) | | | | | | | |
| (A) Polymerizable | Monofunctional | | 4.8 | 4.1 | | | | |
| compound 3 | acrylate | | | | | | | |
| | (aromatic) | | | | | | | |
| Polymerizable | Difunctional | | | | 20 | 40 | 70 | |
| compound 4 | methacrylate | | | | | | | |
| Polymerizable | Difunctional | 2 | | | | | | |
| compound 5 | methacrylate | | | | | | | |
| Polymerizable | Monofunctional | | | | | | | 51 |
| compound 6 | acrylate | | | | | | | |
| (C) Polymerizable | Penta- and hexa- | 8 | 4.7 | 2 | | | | |
| compound 7 | functional | | | | | | | |
| | acrylate | | | | | | | |
| (C) Polymerizable | Trifunctional | | | | | | | |
| compound 8 | acrylate | | | | | | | |
| (C) Polymerizable | Trifunctional | | | | | | | 29 |
| compound 9 | acrylate | | | | | | | |
| Tackifier 1 | Tackifier | | | | | | | |
| Leveling | Leveling | 1 | 1 | 1 | 1 | 1 | 1 | 1 |
| agent 1 | agent | | | | | | | |
| Photopolymerization | Curing | 3 | 3 | 3 | 3 | 3 | 3 | 3 |
| initiator 1 | agent | | | | | | | |
| Physical | tan δ | 1.7 | 2.5 | 3.3 | 1.6 | 0.7 | 0.3 | 0.8 |
| properties | Tg (° C.) | 38 | 31 | 31 | 31 | 41 | 79 | 49 |
| | Refractive | 1.59 | 1.59 | 1.59 | 1.58 | 1.56 | 1.54 | 1.55 |
| | index | | | | | | | |
| | Viscosity @25° C. | 27 | 23 | 29 | 21 | 18 | 15 | 25 |
| Evaluation | CVD | A | B | B | B | A | A | C |
| | Inkjet | A | A | A | A | A | A | A |
| | jetting | | | | | | | |
| | stability | | | | | | | |
| | Film | C | A | B | C | D | D | A |
| | bending | | | | | | | |
| | following | | | | | | | |
| | test | | | | | | | |

In Table 1, the unit of each component is part by mass.

From Table 1, in each of Examples, a cured product having flexibility and a preferred surface hardness was obtained, and the effect of suppressing damage to the organic EL element due to CVD deposition and the inkjet ejecting stability were also excellent.

Priority is claimed on Japanese Patent Application No. 2022-017906, filed Feb. 8, 2022, the disclosure of which is incorporated herein by reference.

### REFERENCE SIGNS LIST

10 light-emitting element
21 barrier layer, touch panel layer, or surface protective layer
22 sealing layer, overcoat layer, or barrier layer
23 flattening layer or sealing layer
24 barrier layer
50 base material layer
100 display device

1. An ultraviolet-curable resin composition comprising:
a component (A) which is a monofunctional aromatic (meth)acrylate having one aromatic ring; and
a component (B) which is a monofunctional aromatic (meth)acrylate having two or more aromatic rings,
wherein a total content of the component (A) and the component (B) is 70 parts by mass or more with respect to 100 parts by mass of a total content of polymerizable compounds in the ultraviolet-curable resin composition.

2. The ultraviolet-curable resin composition according to claim 1, further comprising:
a component (C) which is a tri- or higher functional (meth)acrylate.

3. The ultraviolet-curable resin composition according to claim 1,
wherein a viscosity measured by an E-type viscometer under conditions of 25° C. and 20 rpm is 50 mPa·s or less.

4. The ultraviolet-curable resin composition according to claim 1,
wherein a peak value of tan δ in a viscoelasticity measurement of a cured film of the ultraviolet-curable resin composition is 1.4 or more.

5. The ultraviolet-curable resin composition according to claim 1,
wherein a refractive index of a cured film of the ultraviolet-curable resin composition is 1.57 or more.

6. The ultraviolet-curable resin composition according to claim 1,
wherein a glass transition temperature Tg of a cured film of the ultraviolet-curable resin composition is 60° C. or lower.

7. The ultraviolet-curable resin composition according to claim 1,
wherein a total content of a di- or higher functional (meth)acrylate in the ultraviolet-curable resin composition is 30 parts by mass or less with respect to 100 parts by mass of the total of the polymerizable compounds.

8. The ultraviolet-curable resin composition according to claim 1,
wherein the component (B) is a compound having a biphenyl skeleton.

9. The ultraviolet-curable resin composition according to claim 1,
wherein the component (B) is an ether-modified aromatic (meth)acrylate.

10. The ultraviolet-curable resin composition according to claim 1,
wherein a content of the component (C) which is the tri- or higher functional (meth)acrylate in the ultraviolet-curable resin composition is 10 parts by mass or less with respect to 100 parts by mass of the total of the polymerizable compounds.

11. The ultraviolet-curable resin composition according to claim 1, further comprising:
a photopolymerization initiator.

12. The ultraviolet-curable resin composition according to claim 11,
wherein the photopolymerization initiator is diphenyl(2,4,6-trimethylbenzoyl)phosphine oxide (TPO).

13. The ultraviolet-curable resin composition according to claim 1,
wherein the ultraviolet-curable resin composition is used for coating by an inkjet method.

14. The ultraviolet-curable resin composition according to claim 1,
wherein the ultraviolet-curable resin composition is for a display element.

15. The ultraviolet-curable resin composition according to claim 14,
wherein the display element is an organic electroluminescence element.

16. A display device comprising:
a substrate;
a light-emitting element disposed over the substrate; and
a resin layer covering the light-emitting element,
wherein the resin layer includes a cured product of the ultraviolet-curable resin composition according to claim 1.

17. The display device according to claim 16,
wherein the light-emitting element includes an organic electroluminescence element.
